(19) United States
(12) Patent Application Publication
(10) Pub. No.: US 2006/0138558 A1
(43) Pub. Date: Jun. 29, 2006

(54) Semiconductor memory device and method of fabricating the same

(75) Inventor: Mutsuo Morikado, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/115,106

(22) Filed: Apr. 27, 2005

(30) Foreign Application Priority Data
Dec. 24, 2004 (JP) 2004-372720

(51) Int. Cl. H01L 29/76

(52) U.S. Cl. 257/377

(57) ABSTRACT

A semiconductor memory device includes: a semiconductor device base having an insulating substrate and a semiconductor layer overlying it; a cell array formed on the semiconductor device base with memory cells disposed in such a manner that each of source and drain regions is shared by adjacent two memory cells arranged in a direction, the memory cell having an electrically floating channel body to store data defined by a carrier accumulation state of the channel body; and silicide films formed on the source and drain regions of the memory cell, wherein the memory cell is formed in such a state that at least a part of at least one of source and drain regions is lessened in width in comparison with the cannel region.

### CROSS-REFERENCE TO RELATED APPLICATION

This application is based on and claims the benefit of priority from the prior Japanese Patent Application No. 2004-372720, filed on Dec. 24, 2004, the entire contents of which are incorporated herein by reference.

### BACKGROUND OF THE INVENTION

1. Field of the Invention

This invention relates to a semiconductor memory device and a method of fabricating the same. More particularly, the invention relates to a memory device with memory cells formed on a SOI substrate, each memory cell having an electrically floating channel body to store data defined by a carrier accumulation state of the channel body.

2. Description of Related Art

Recently, for the purpose of alternative use or replacement of conventional DRAMs, a semiconductor memory device that has a more simplified cell structure for enabling achievement of dynamic storability has been provided. A memory cell (i.e., cell transistor) is formed of a single transistor which has an electrically floating body (channel body) as formed on a silicon-on-insulator (SOI) substrate. This memory cell stores two-value data as follows: a first data (for example, logic “1” data) is stored as a state that an excess number of majority carriers are accumulated or stored in the body; and a second data (for example, logic “0” data) is stored as a state that the excessive majority carriers are drawn out from the body. Such the memory has been described in, for example, Unexamined Japanese Patent Application Publication No. 2003-68877.

The memory cell of the type stated above will be referred to hereinafter as a “floating-body cell (FBC)”. A semiconductor memory using FBCs will be referred to as a “FBC memory”. The FBC memory makes use of no capacitors unlike currently available standard DRAM chips so that the memory cell is simpler in memory cell array structure and smaller in unit cell area than ever before. Thus, the FBC memory is readily scalable in cell structure and advantageously offers much enhanced on-chip integration capabilities.

For writing logic “1” data in the FBC memory, impact ionization near the drain of a memory cell is utilized. More specifically, with giving an appropriate bias condition for permitting flow of a significant channel current in the memory cell, majority carriers (holes in case of n-channel memory cell) are generated by impact ionization and stored in the floating body. Writing logic “0” data is performed by setting a PN junction between the drain and the body in a forward bias state, thereby releasing the body's majority carries toward the drain side.

A difference between carrier storage states of the floating body appears as a difference between threshold voltages of the cell transistor. Thus, detect whether an appreciable cell current is present or absent, alternatively, whether the cell current is large or small in magnitude, by applying a read voltage to the gate of the cell transistor, and it is possible to determine or sense whether the resultant read data is a logic “0” or “1”. The carrier accumulation state of the body may be retained with applying a certain holding voltage to the gate.

To achieve highly integrated FBC memories, it is desirable to use such an arrangement that adjacent two memory cells arranged in the direction of the bit line share a source/drain layer without disposing a device isolation area between them. One problem with this, however, is that data reliability is reduced.

The problem will be explained in detail with reference to FIG. 20, which shows two memory cells MTi and MTi+1 disposed as adjacent in the direction of a bit line (BL). Each memory cell is formed on a p-type silicon layer 3 serving as a channel body. The silicon layer 3 is formed on a silicon substrate 1 with an insulating film 2 interposed therebetween. Gate electrodes 4 of the memory cells MTi and MTi+1 are formed as elongated in the direction perpendicular to the drawing plain to constitute word lines WLi and WLi+1, respectively.

The two memory cells MTi and MTi+1 share an n-type diffusion layer (i.e., drain layer) 5, to which the bit line BL is contacted. Other n-type layers (i.e., source layers) of these transistors are shared by these memory cells and adjacent ones (not shown), with which source lines are contacted.

FIG. 20 shows carrier movement in the channel body in a state that “0” write is performed in one memory cell MTi within two memory cells MTi and MTi+1. In this case, with applying a forward bias between the drain diffusion layer 5 connected to the bit line BL and the channel body 3, holes (i.e., majority carriers designated by symbol “+”) in the channel body 3 of the cell transistor MTi are drawn to the drain layer 5.

At this time, part of the holes drawn in the drain diffusion layer 5 passes through this layer 5 to be injected into the channel body of the adjacent memory cell MTi1+1. This is a result of that a parasitic PNP transistor formed between two channel bodies of the memory cells MTi and MTi+1 becomes on. Therefore, if the memory cell MTi+1 is storing “0” data, “1” data may be erroneously written into it. This erroneous write (i.e., data destruction) will be referred to as “bipolar disturbance” because it is due to a parasitic bipolar transistor.

As described above, the conventional FBC memory has a problem that approach for achieving high integration density leads to bipolar disturbance, i.e., reduction of data reliability due to interference between adjacent memory cells. If adjacent two memory cells are perfectly isolated from each other, the bipolar disturbance will be solved. However, this ruins the feature of the FBC memory that it may be integrated with a high density. Therefore, it is required to reduce the bipolar disturbance of memory cells without ruining the feature of the FBC memory.

### SUMMARY OF THE INVENTION

According to an aspect of the present invention, there is provided a semiconductor memory device including:

a semiconductor device base having an insulating substrate and a semiconductor layer overlying it;

a cell array formed on the semiconductor device base with memory cells disposed in such a manner that each of source and drain regions is shared by adjacent two memory cells arranged in a direction, the memory cell having an electrically floating channel body to store data defined by a carrier accumulation state of the channel body; and

silicide films formed on the source and drain regions of the memory cell, wherein

the memory cell is formed in such a state that at least a part of at least one of source and drain regions is lessened in width in comparison with the cannel region.

### BRIEF DESCRIPTION OF THE DRAWINGS

FIG. 1 is a plan view of a cell array area of a semiconductor device base used for an FBC memory in accordance with Embodiment 1 of the present invention.

FIG. 2 is a sectional view taken along I-I′ line of FIG. 1.

FIG. 3 is a sectional view taken along II-II′ line of FIG. 1.

FIG. 4 is a plan view of a memory cell array of the FBC memory.

FIG. 5 is a sectional view taken along I-I′ line of FIG. 4.

FIG. 6 is a sectional view taken along II-II′ line of FIG. 1.

FIG. 7 is a sectional view for explaining the steps of forming the gate electrodes and n-type diffusion layers in the Embodiment 1.

FIG. 8 is a sectional view for explaining the steps of forming insulating spacers and n⁺-type diffusion layers in the Embodiment 1.

FIG. 9 is a sectional view for explaining the step of forming the silicide films in the Embodiment 1.

FIG. 10 is a plan view of the cell array area and the peripheral circuit area.

FIG. 11 shows sectional views of the cell array area (I-I′) and peripheral circuit area (III-III′) in FIG. 10.

FIG. 12 is a plan view of a cell array in accordance with Embodiment 1.

FIG. 13 is a sectional view taken along I-I′ line of FIG. 12.

FIG. 14 is a plan view of a cell array in accordance with Embodiment 3.

FIG. 15 is a sectional view taken along I-I′ line of FIG. 14.

FIG. 16 is a plan view of a cell array in accordance with Embodiment 4.

FIG. 17 is a sectional view for explaining the steps of forming gate electrode and insulating spacers in Embodiment 5.

FIG. 18 is a sectional view for explaining the step of epitaxial growth of silicon layers in the Embodiment 5.

FIG. 19 is a sectional view for explaining the step of forming silicide films in the Embodiment 5.

FIG. 20 is a diagram for explaining bipolar disturbance in a conventional FBC memory.

### DETAILED DESCRIPTION OF THE EMBODIMENTS

Illustrative embodiments of this invention will be explained with reference to the accompanying drawings below.

### Embodiment 1

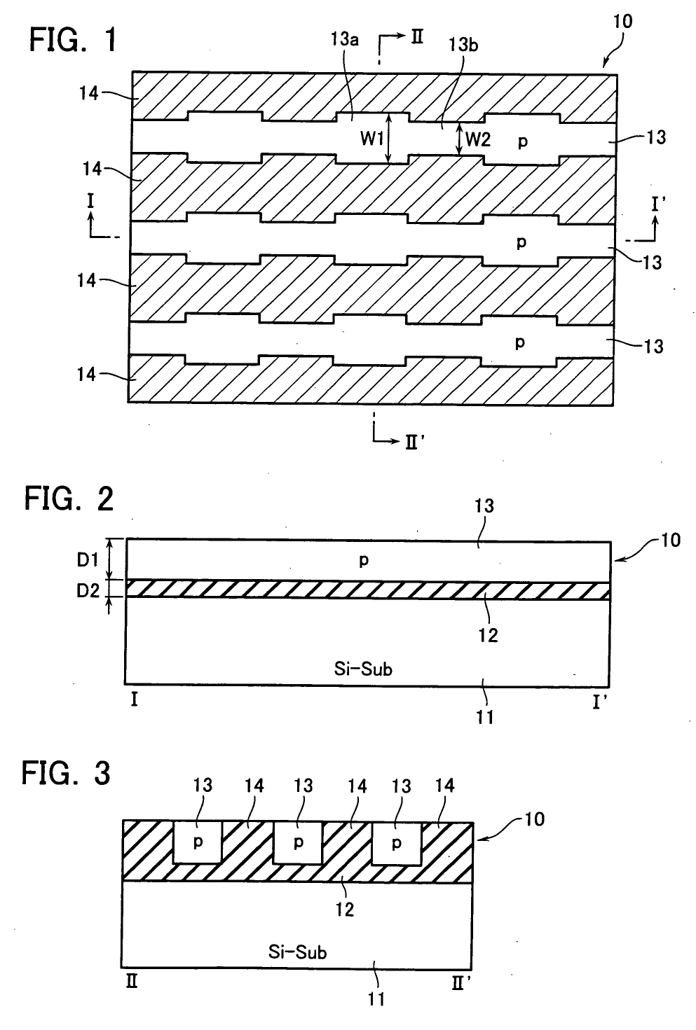

FIG. 1 is a plan view of a cell array area in a semiconductor device base 10, which is used for an FBC memory in accordance with an embodiment 1, and FIGS. 2 and 3 are I-I′ and II-II′ sectional views thereof, respectively. The semiconductor device base 10 is a so-called SOI (Silicon On Insulator) substrate, which has an insulating substrate and a p-type silicon layer 13 overlying it. The insulating substrate is a silicon substrate 11 covered with an insulation film 12 such as silicon oxide. The silicon layer 13 is about 50-60 [nm] thick (for example, 55 nm), and the silicon oxide film 12 is 25 [nm] thick.

In the cell array area, the silicon layer 13 is patterned and divided into a plurality of substantially stripe-shaped areas, and device isolation film 14 is buried between the respective areas. That is, the stripe-shaped p-type layers 13 serve as device formation regions respectively, which are isolated from the substrate 11 by the insulating film 12 and isolated from each other by the device isolating film 14.

Each silicon layer 13 is, as shown in FIG. 1, patterned into such a state that first silicon areas 13a with a width W1 and second silicon areas 13b with a width W2 smaller than W1 are alternately arranged at a certain pitch. The first silicon areas 13a serve as channel regions, on which gate electrodes of memory cells are formed, and the width W1 becomes a so-called “channel width”. The second silicon areas 13b serve as source and drain formation areas. In an example, these widths of the respective silicon areas are set as follows: W1=150[nm]; W2=100 [nm].

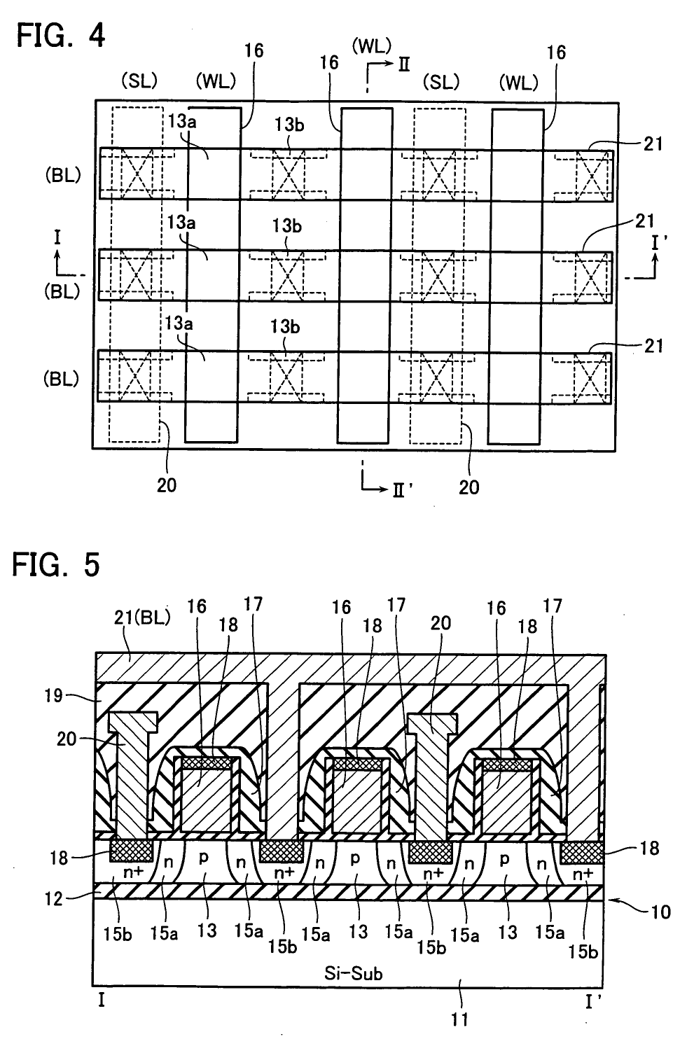

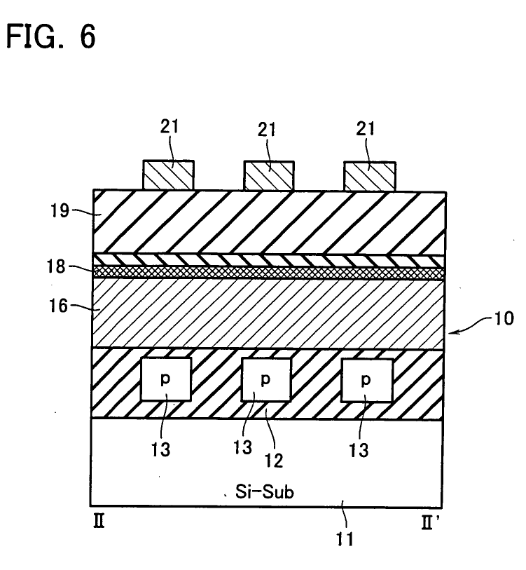

FIG. 4 show a layout of a cell array formed on the device base 10, and FIGS. 5 and 6 show I-I′ and II-II′ sectional views thereof, respectively. A gate electrode 16 of a memory cell (i.e., cell transistor) is formed to be continued as crossing the first silicon area 13a of the silicon layer (i.e., device formation region) 13, and serves as a word line WL. Source and drain regions 15 are formed as self-aligned to the gate electrode 16, and as overlapped the second silicon area 13b, so that a memory cell is formed to have an electrically floating p-type channel body.

The source and drain regions 15 are, in detail, formed of n-type diffusion layers 15a self-aligned to the gate electrode 16 and n⁺-type diffusion layers 15b self-aligned to the insulating spacers 17 formed on the side walls of the gate electrode 16. Adjacent two memory cells arranged in the direction perpendicular to the word line WL share a source/drain layer.

On the top surfaces of the gate electrode 16 and the source/drain regions 15, self-aligned metal silicide (i.e., salicide) films 18 are formed. These silicide films 18 are formed with the steps of: forming a metal film such as Ni film on the silicon layer; and then thermal-annealing for causing the metal film to react with silicon. In this reaction step, as the silicidation area is less in width, the silicidation reaction is made progress more deeply.

In the cell array area in accordance with this embodiment, source/drain areas have been formed to have width W2 smaller than the remaining areas in the p-type silicon layer 13. Due to this fact, the silicide films 18 formed on the source/drain regions of the memory cell become thicker than those in peripheral circuitry. This point will be explained in detail later.

The cell array area including memory cells are covered with a barrier film such as a silicon nitride film, and an interlayer dielectric film 19 is deposited thereon. On the interlayer dielectric film 19, bit lines (BL) 21 are formed of a metal film. Each bit line 21 is formed continuously as crossing the word lines WL and contacted to one diffusion layers (i.e., common drain layers) 15 of the memory cells. In the interlayer dielectric film 19, source lines (SL) 20 are buried. Each source line 20 is formed as continued in the direction of the word line WL to couple other diffusion layers (i.e., common source layers) 15 of the memory cells which are arranged in the direction of the word line WL in common.

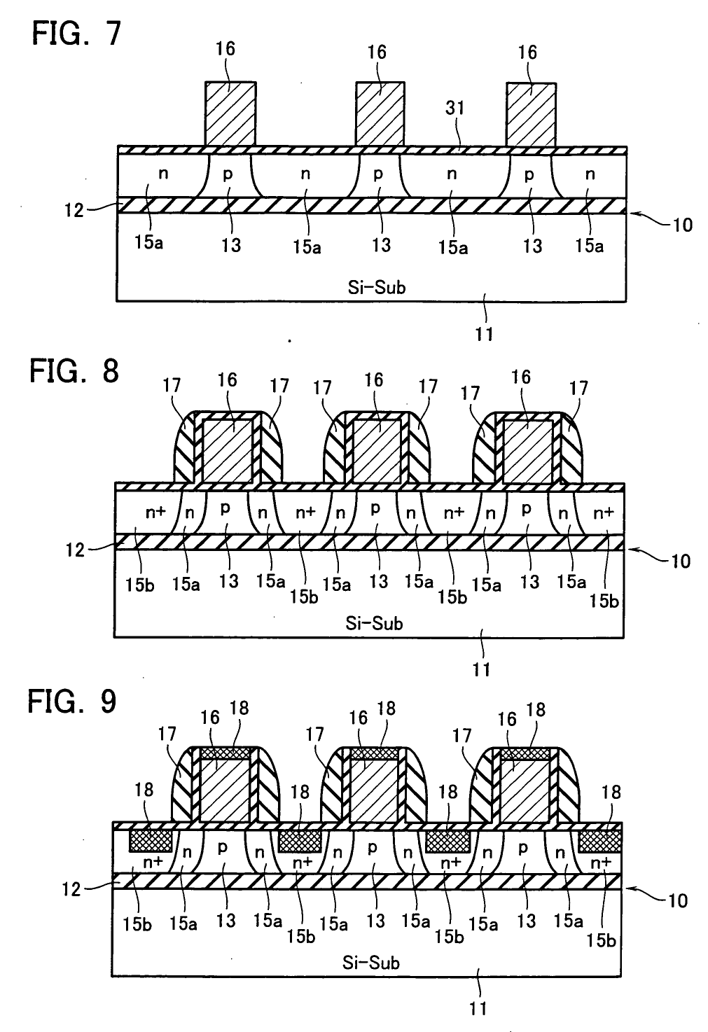

Next, a fabrication process of the FBC memory in accordance with this embodiment will be explained referring to FIGS. 7 to 9, which show sectional views in the respective steps, corresponding to FIG. 5.

As shown in FIG. 7, after having formed gate insulating film 31 on the p-type silicon layer 13 of the device base 10, a gate conductive film, for example polycrystalline silicon (polysilicon) film is deposited thereon by CVD (Chemical Vapor Deposition) and then etched by RIE (Reactive Ion Etching), whereby gate electrode 16 serving as a word line is formed in the cell array area. Following it ion implantation is performed to form n-type diffusion layers 15a in the source/drain region, which are self-aligned to the gate electrodes 16. The n-type layers 15a are formed in the p-type layer 13 in the cell array area with such a depth as reaching bottom (i.e., as reaching the bottom insulating film 12).

Next, a silicon nitride film is deposited by, for example, CVD, and then it is etched-back by RIE, so that insulating spacers 17 are formed, as shown in FIG. 8, on either side wall of the gate electrode 16. Thereafter, ion implantation is performed again, whereby n⁺-type diffusion layers 15b self-aligned to the insulating spacers 17 are formed in the source/drain region. The n⁺-type layers 15a also are formed in the p-type layer 13 with such a depth as reaching bottom.

After oxide film removing process for the surface of the gate electrodes 16 and source/drain regions 15, a metal film such as Ni or Co is deposited, and the wafer is subjected to thermal anneal. As a result, as shown in FIG. 9, metal silicide films 18 are formed on the top surfaces of the gate electrodes 16 and source/drain regions 15. Since the source/drain regions 15 have been narrowed in width, the silicide films 18 are formed on the source/drain regions 15 as being thicker than those in the peripheral circuit area.

Following it, deposition of the interlayer insulating film and metal wiring formation are sequentially performed.

In the FBC memory in accordance with this embodiment, as described above, as a result of that the source/drain regions 15 are narrowed in width, the silicide films 18 are made thick at the top surfaces of the source/drain regions 15. That is, decreasing of source/drain region width and silicon layer thickness thereof leads to lateral resistance increasing of the source/drain region, resulting in that bipolar disturbance may be suppressed. In addition, as a result of that silicide film 18 is formed on the source/drain region 15, the source/drain layer becomes a defective crystal layer, in which carrier life time thereof is shortened. This also is effective for suppressing the bipolar disturbance.

It should be noted that the p-type silicon layer (i.e., SOI film) has not been thinned in this embodiment. If the p-type silicon layer is made thinner than that in current use, it may bring about some inconveniences such as: process margin is decreased; it becomes difficult to select an optimum ion implantation condition for forming the source/drain layers; source/drain resistance is not reduced in spite of using silicide process. In accordance with this embodiment, these inconveniences may be solved.

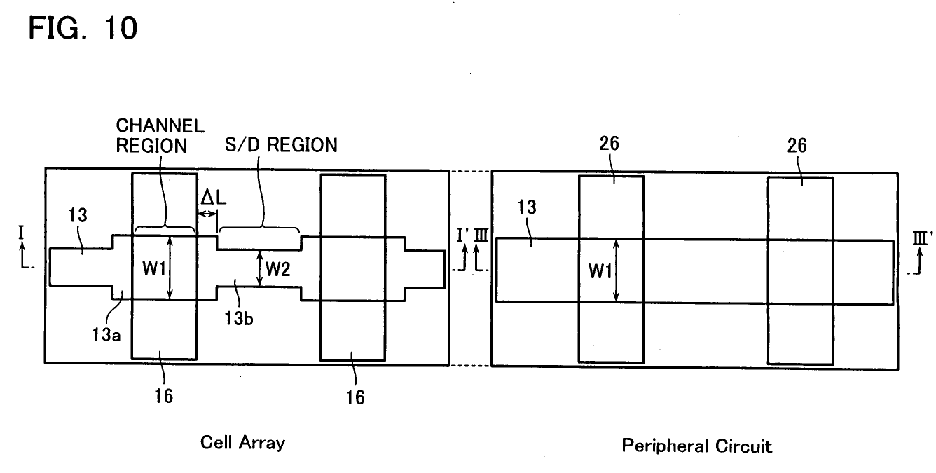

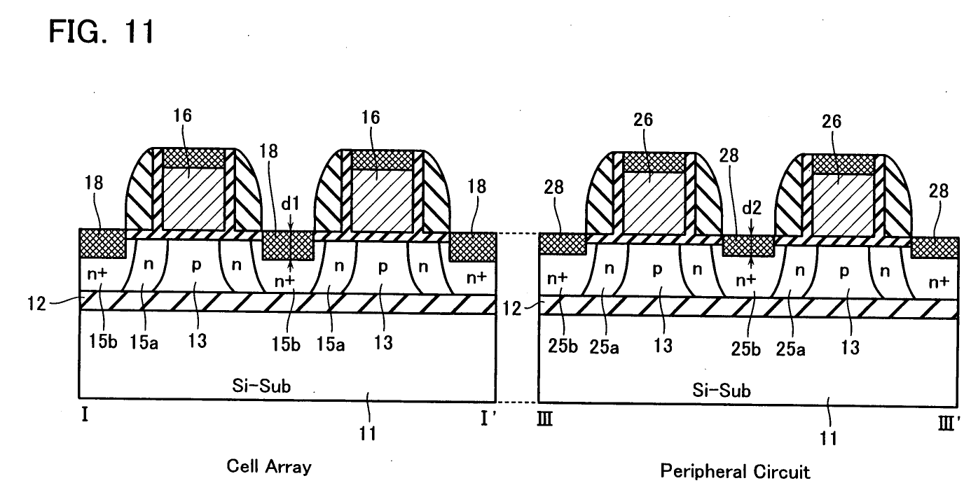

FIG. 10 shows a layout of memory cells in the cell array area in comparison with that of logic transistors in peripheral circuitry. FIG. 11 shows sectional views of the cell array area (taken along I-I′ line) and peripheral circuit area (taken along III-III′ line).

In the cell array area, the device formation region 13 has first silicon areas (channel regions) 13a with a width W1 and second silicon areas (source/drain regions) 13b with a width W2(<W1). There is taken a margin of ΔL for allowing a certain mask alignment difference outside the channel region. By contrast, in the peripheral circuit area, the device formation region 13 is patterned to have a constant width W1, while the gate electrodes 26 formed thereon are patterned to have the same width as the gate electrodes 16 of the memory cells.

As shown in FIG. 11, n-type diffusion layers 25a and n⁺-type diffusion layers 25b are formed at the source/drain regions 25 of the peripheral circuit transistors simultaneously with n-type diffusion layers 15a and n⁺-type diffusion layers 15b, respectively, at the source/drain regions 15 of the memory cells. Silicide films 28 are formed on the top surfaces of the gate electrodes 26 and source/drain regions 25 simultaneously with the silicide films 18 in the cell array area.

Since the source/drain regions 15 of the memory cells are narrowed in width in comparison with the source/drain regions 25 of the logic transistors, the thickness d1 of the silicide films 18 formed on the source/drain regions 15 in the cell array area becomes larger than the thickness d2 of the silicide films 28 formed on the source/drain regions 25 in the peripheral circuit area. One example is as follows: d1=35 [nm]; and d2=25 [nm].

Supposing that the p-type silicon layer 13 is 55 [nm] thick as described above, about 20 [nm] thick silicon layers will be remained under the silicide films 18 of the source/drain regions 15 in the cell array area, while in the peripheral circuit area, about 30[nm] thick silicon layers will be remained under the silicide films 28 of the source/drain regions 25 in the peripheral circuit area.

Therefore, according to this embodiment, lateral resistance of the source/drain region is increased, and it leads to suppressing the bipolar disturbance, while in the peripheral circuit area source/drain resistance increase may be suppressed, thereby achieving high-rate performance.

### Embodiment 2

Although in the above-described Embodiment 1 the source/drain region's width is lessened in comparison with the channel region's width in the cell array area, it is effective that only wiring contact areas in the source/drain regions are lessened in width.

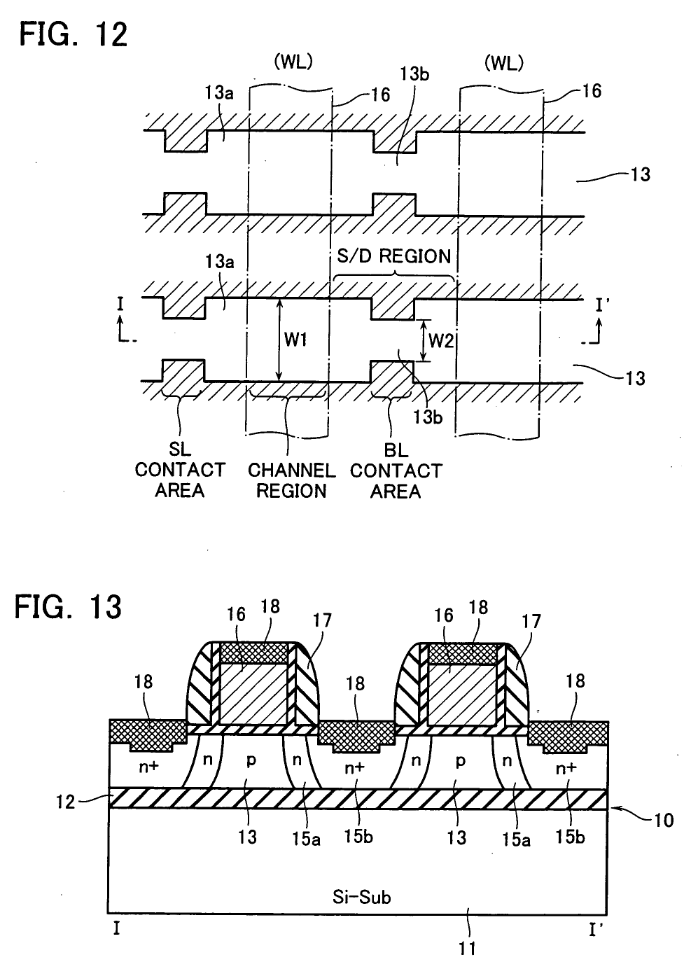

FIG. 12 shows a cell array layout in accordance with Embodiment 2, and FIG. 13 shows a sectional view taken along I-I′ line of FIG. 12. First silicon areas 13a serving as channel regions in the substantially stripe-shaped p-type silicon layer 13 have a width of W1, and the source/drain regions have the same width W1 in a certain range extended from the channel region. Second silicon areas 13b serving as wiring contact areas, to which the bit line (BL) and source line (SL) are contacted, are lessened in width as being W2(<W1).

The section shown in FIG. 13 is substantially the same as that shown in FIG. 9 in accordance with Embodiment 1, but the silicide films 18 are formed on the source/drain regions 15 in such a state that the wiring contact areas are thickened in comparison with the remaining portions due to the width change from W1 to W2 in the source/drain regions 15.

Supposing that, for example, p-type silicon layer 13 is 55 [nm] thick as well as Embodiment 1; the channel region has a width of W1=150 [nm]; and the wiring contact area of the source/drain region has a width of W2=100 [nm], about 35 [nm] thick silicide film 18 is formed on the wiring contact area of the source/drain region, resulting in that about 20 [nm] thick silicon layers will be remained under the silicide film 18.

According to this Embodiment 2, advantageous effects may be obtained as similar to Embodiment 1.

### Embodiment 3

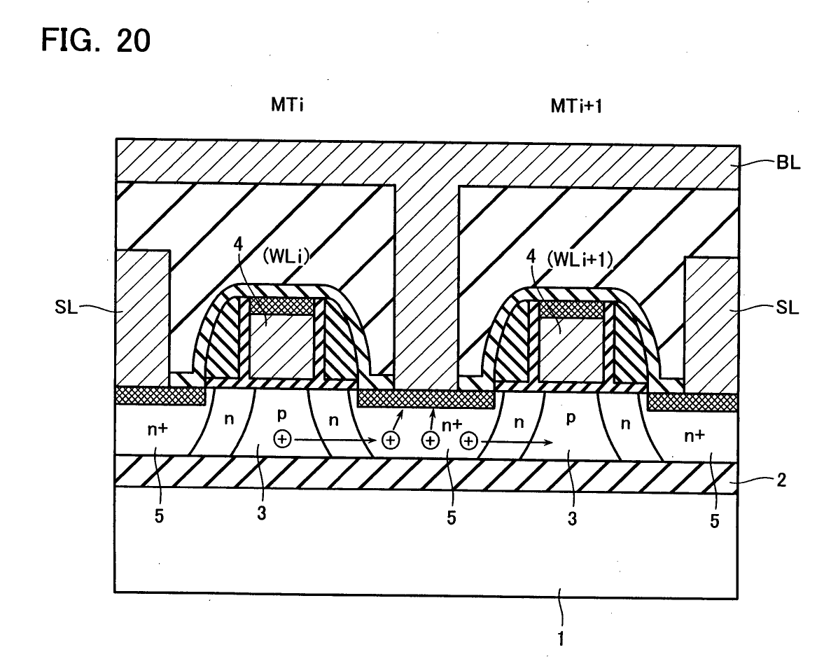

In the above-described Embodiments 1 and 2, both of source/drain regions are lessened in width. This fact is preferable for the following reason. Lateral resistance increasing of the drain region, to which the bit line BL is contacted, is effective for suppressing the bipolar disturbance at “0” write time, when the bit line voltage is pulled down, as explained in FIG. 20. The above-described bipolar disturbance is due to interference between adjacent cells sharing a drain.

On the other hand, it should be noted that there is another bipolar disturbance between adjacent cells sharing a source. At “1” write time, when both of bit line and word line are applied with positive voltages, some of the holes accumulated in the target channel body are injected into and passed trough a common source region to be injected into an adjacent cell's channel body. This is because of that a parasitic PNP bipolar transistor is forward-biased to turn on when the target channel body (p) becomes positive due to capacitive coupling from the gate, and the common source (n) is held at, for example, ground potential.

Considering these facts, it is desirable that both of source/drain regions are lessened in width. However, this invention will be adapted to such a case where bipolar disturbance is suppressed at only one of source and drain regions.

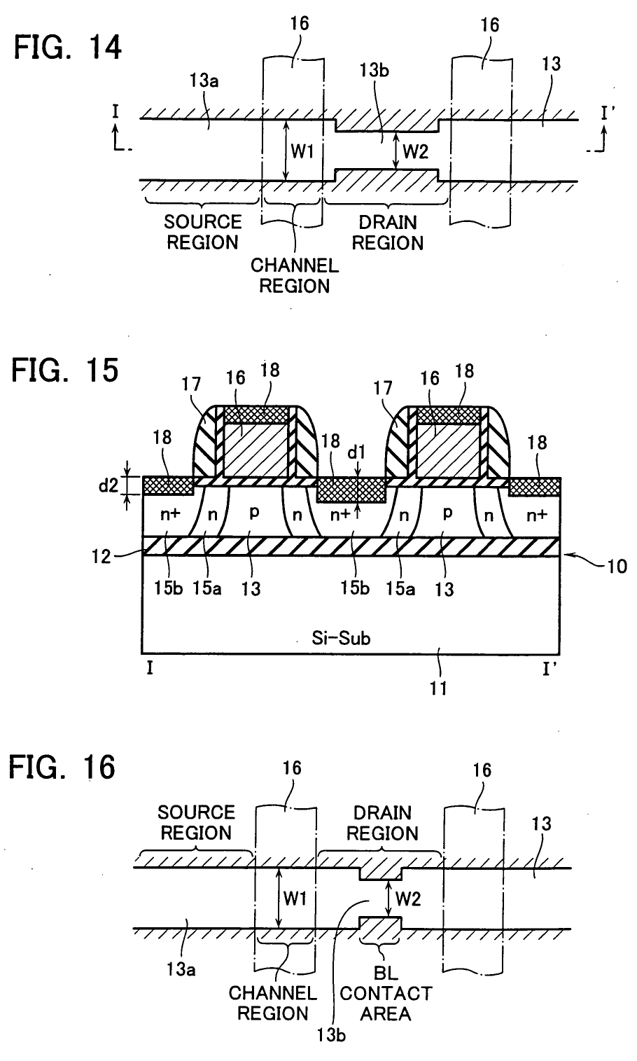

For example, FIG. 14 shows a cell layout in accordance with Embodiment 3, in which first silicon areas 13a serving as channel regions and source regions have a width of W1, and second silicon areas 13b serving as drain regions have a width of W2(<W1), comparing with FIGS. 1 and 2. FIG. 15 is a sectional view taken along line I-I′ of FIG. 14. As similar to Embodiment 1, suppose that the p-type silicon layer 13 is about 50 [nm] to 60 [nm] thick (for example 55 [nm]), and the device formation region widths W1 and W2 are set as follows: W1=150 [nm], W2=100 [nm].

As shown in FIG. 15, the silicide films 18 formed on the drain regions are thicker than those formed on the source regions. In detail, supposing that drain side silicide film is d1 thick; and source side silicide film is d2 thick, it will be provided the following expression: d2<d1. In case the device formation region is patterned to have a width of W1 in the peripheral circuit region as similar to Embodiment 1 explained with FIGS. 10 and 11, the source side silicide film thickness d2 of the memory cell in this Embodiment 3 is the same as that of silicide films formed on source and drain regions of the logic transistor in the peripheral circuit.

According to this embodiment 3 as described above, the bipolar disturbance on the drain side of the memory cell may be suppressed.

### Embodiment 4

FIG. 16 shows a cell array layout in accordance with Embodiment 4, in which only drain side contact area (i.e., bit line contact area) in the source and drain regions is overlapped the second silicon area 13b with width W2; and the remaining portions are formed on the first silicon area 13a with width W1. Although the sectional view is not shown, data disturbance due to the parasitic bipolar transistor on the drain side may be suppressed under the condition that thicknesses of the p-type silicon layer and silicide film formed on the narrowed drain region are set to be substantially the same as those in Embodiments 1 and 2.

### Embodiment 5

In the above-described Embodiments 1-4, the p-type silicon layer 13 is 50-60 [nm] thick, and remained silicon layer underlying the silicide film formed on the source/drain region is about 20 [nm] thick. Considering a view point for suppressing bipolar disturbance of the FBC memory, it is desired to lessen the thickness of the remained silicon layer in the source/drain region as possible.

However, as the cell array is more miniaturized, it may lead to another inconvenience. For example, suppose that the p-type silicon layer is 40 [nm] thick; channel region width W1 is W1=120 [nm]; and source/drain region width W2 is W2=80 [nm]. If, in this case, the silicide film formed on the source/drain region becomes 35 [nm] thick or more, the silicon layer remained under the silicide film becomes 5 [nm] thick or less. As the source/drain layer is thinned to the above-described level, the source/drain resistance becomes excessively high, and it will make the FBC memory impossible to maintain a practical read/write performance.

To solve such the inconvenience, it becomes effective to use such a so-called “elevated source/drain structure” that a silicon layer is formed on the source/drain region by selective epitaxial growth.

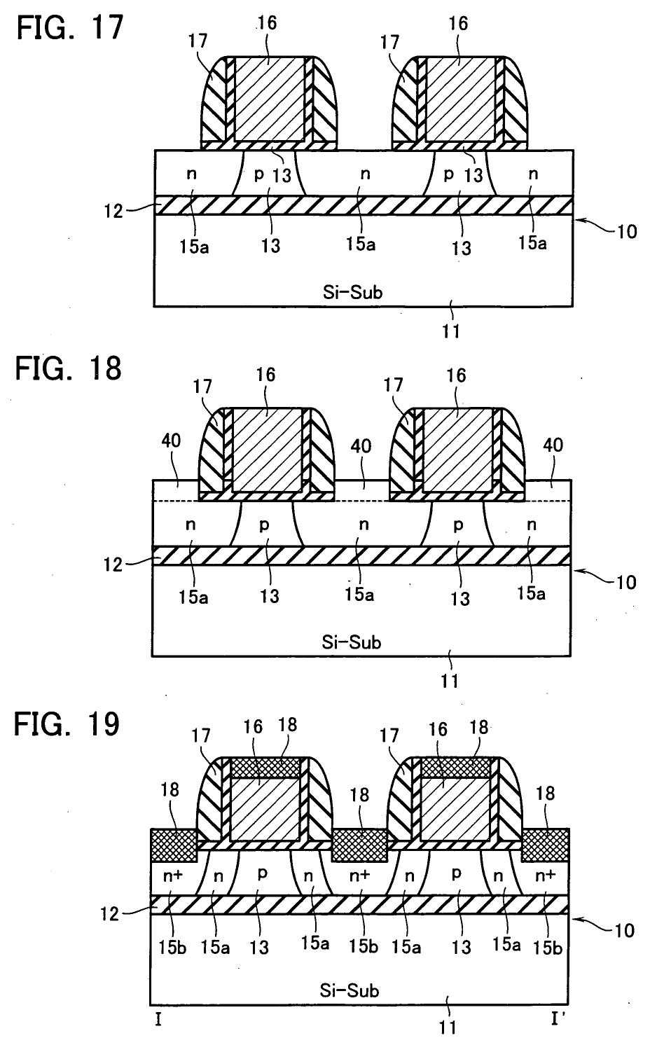

FIGS. 17 to 19 show FBC memory fabricating steps in accordance with Embodiment 5, in which the elevated source/drain structure is used, comparing with FIGS. 7 to 9 in accordance with Embodiment 1. The p-type silicon layer 13 is thinner than those in Embodiments 1-4, and it is, for example, set to be 40 [nm]. The layout of the device formation region is not shown, but patterned as similar to either one of FIGS. 1, 12, 14 and 16. Suppose that channel region width W1 is W1=120 [nm]; and width W2 of the narrowed area of the source/drain region is W2=80 [nm].

As shown in FIG. 17, gate electrodes 16 are patterned, and n-type layers 15a are formed in the source/drain regions, and then insulating spacers 17 are formed on the side wall of the gate electrodes 16. So far, the fabrication steps are the same as those in Embodiment 1.

Thereafter in this Embodiment 5, as shown in FIG. 18; silicon layers 40 are selectively and epitaxially grown on the top surfaces of the source/drain region. The thickness of the silicon layer 40 is about 15 [nm]. Silicon layers are also formed on the gate electrodes 16, but these are ignored in FIG. 18.

Then as shown in FIG. 19, n⁺-type diffusion layers 15b are formed in the source/drain region as self-aligned to the insulating spacers 17 by ion implantation. Following this step, a metal film such as Ni film is formed, and then thermal-annealing are performed so that metal silicide films 18 are formed on the gate electrodes 16 and source/drain regions 15.

If the silicide films 18 formed on the source/drain regions are about 35 [nm] thick, it is possible to leave silicon layers of about 20 [nm], at least 15 [nm] thick or more, just under the silicide films 18. Therefore, according to this Embodiment 5, in case the cell array is further miniaturized, the bipolar disturbance may be suppressed without increasing the source/drain resistance.

This invention is not limited to the above-described embodiment. For example, while it has been explained that the memory cell has an NMOS transistor structure, it should be appreciated that the memory cell may be formed with a PMOS transistor structure. Further, it will be understood by those skilled in the art that various changes in form and detail may be made without departing from the spirit, scope, and teaching of the invention.

What is claimed is:

1. A semiconductor memory device comprising:
a semiconductor device base having an insulating substrate and a semiconductor layer overlying it;
a cell array formed on said semiconductor device base with memory cells disposed in such a manner that each of source and drain regions is shared by adjacent two memory cells arranged in a direction, said memory cell having an electrically floating channel body to store data defined by a carrier accumulation state of the channel body; and
silicide films formed on the source and drain regions of said memory cell, wherein
said memory cell is formed in such a state that at least a part of at least one of source and drain regions is lessened in width in comparison with the cannel region.

2. The semiconductor memory device according to claim 1, wherein
the source and drain regions of said memory cell have a width smaller than the channel region.

3. The semiconductor memory device according to claim 1, wherein
wiring contact areas in the source and drain regions of said memory cell have a width smaller than the channel region.

4. The semiconductor memory device according to claim 1, wherein
one of the source and drain regions of said memory cell has a width smaller than the channel region.

5. The semiconductor memory device according to claim 1, wherein
a wiring contact area of one of the source and drain regions of said memory cell has a width smaller than the channel region.

6. The semiconductor memory device according to claim 1, wherein
the source and drain regions are elevated by selective epitaxial growth before having formed the silicide films.

7. A semiconductor memory device comprising:
a semiconductor device base having an insulating substrate and a semiconductor layer overlying it, a plurality of device formation regions being defined on semiconductor device base, first semiconductor areas and second semiconductor areas being alternately arranged at a certain pitch in each the device formation region, the second semiconductor area having a width smaller than that of the first semiconductor area;
a cell array formed on said semiconductor device base with memory cells disposed in such a manner that adjacent two memory cells share source and drain regions, said memory cell having an electrically floating channel body and a gate electrode to store data defined by a carrier accumulation state of the channel body, the gate electrode being formed as crossing above the first semiconductor area to continue as a word line, at least a part of at least one of the source and drain regions being formed in the second semiconductor area; and
silicide films formed on the source and drain regions of said memory cells.

8. The semiconductor memory device according to claim 7, wherein
the source and drain regions of said memory cell are formed in the second semiconductor areas.

9. The semiconductor memory device according to claim 7, wherein
wiring contact areas in the source and drain regions of said memory cell are formed in the second semiconductor areas.

10. The semiconductor memory device according to claim 7, wherein
one of the source and drain regions of said memory cell is formed in the second semiconductor area.

11. The semiconductor memory device according to claim 7, wherein
a wiring contact area in one of the source and drain regions of said memory cell is formed in the second semiconductor area.

12. The semiconductor memory device according to claim 7, wherein
the source and drain regions are elevated by selective epitaxial growth before having formed the silicide films.

13. The semiconductor memory device according to claim 7, wherein
the source and drain regions of said memory cell comprises: first diffusion layers formed in the semiconductor layer to reach the insulating substrate, the first diffusion layers being self-aligned to the gate electrode; and second diffusion layers formed in the semiconductor layer to reach the insulating substrate, the second diffusion layers being self-aligned to insulating spacers formed on the side wall of the gate electrode.

14. The semiconductor memory device according to claim 7, further comprising:
an interlayer dielectric film formed to cover said cell array: and
bit lines formed on the interlayer dielectric film as continuing in the direction perpendicular to the word line and contacted to drain regions each being shared by two memory cells arranged in the bit line direction.

15. The semiconductor memory device according to claim 14, further comprising:
source lines embedded in the interlayer dielectric layer to be contacted to source regions each being shared by two memory cells arranged in the word line direction.

16. A method of fabricating a semiconductor memory device comprising:
forming a plurality of device formation regions on a semiconductor device base having an insulating substrate and a semiconductor layer overlying it, each device formation region being defined in the semiconductor layer in such a state that first semiconductor areas and second semiconductor areas are alternately arranged at a certain pitch, the second semiconductor area having a width smaller than that of the first semiconductor area;
forming gate electrodes of memory cells on the first semiconductor areas in each device formation regions of said semiconductor device base;
forming source and drain regions of the memory cells in each device formation regions of said semiconductor device base in such a state that each of the source and drain regions is shared by two memory cells disposed adjacent in each device formation region, at least one of the source and drain regions being formed in the second semiconductor area; and
forming silicide films on the top surfaces of the gate electrodes and source drain regions.

17. The method according to claim 16,
wherein the step of forming source and drain regions comprises:
forming first diffusion layers in the semiconductor layer to be self-aligned to the gate electrodes;
forming insulating spacers on either side wall of the gate electrodes; and
forming second diffusion layers in the semiconductor layer to be self-aligned to the insulating spacers.

18. The method according to claim 17, further comprising
forming semiconductor layers on the source and drain regions by selective epitaxial growth after having formed the insulating spacers and prior to forming the second diffusion layers.
